(19) United States
(12) Patent Application Publication
(10) Pub. No.: US 2010/0078054 A1
(43) Pub. Date: Apr. 1, 2010

(54) Thermal Difference Engine

(76) Inventor: Manjirnath Chatterjee, (US)

Correspondence Address: MANJIRNATH A CHATTERJEE, 111 GILBERT #2, SAN FRANCISCO, CA, 94103, US

(21) Appl. No.: 12/239,779

(22) Filed: Sep. 28, 2008

(51) Int. Cl. H01L 35/00; G05F 3/08

(52) U.S. Cl. 136/224; 323/371

(57) ABSTRACT

Closed system heat engines can be used to deliver useful electrical power by harvesting ambient energy in the environment. The present invention provides a means of harvesting these low temperature differences in to useful energy and provides while providing rectification and regulation features.

### RELATED APPLICATIONS

This application claims priority to U.S. provisional Patent Application Ser. No. 60/975,99, which was filed on Sep. 27, 2007. This application is incorporated entirely by reference.

### BACKGROUND OF THE INVENTION

1. Field of the Invention

The invention relates to heat engine devices such as those used for harvesting thermal energy in to another form of energy such as mechanical energy or electrical energy. Specifically the present invention relates to closed cycle (Carnot cycle) heat engines and their practical implementation.

2. Prior Art

Closed cycle heat engines are governed by various types of heat cycles derived from Carnot's law of efficiency and the laws of thermodynamics. Much ambient energy in the form of small temperature differentials exist for harvesting around the planet. However typically simple closed cycle heat engines are inefficient at small temperature differences in typical temperature ranges found on earth (e.g. around 250-320K). For example if a small heat engine is employed with a cold side temperature of 300K and a hot side temperature of 305K then the efficiency is given by Eff=1−[Thot/(Tcold+Thot)]=0.017 or about 1.7% efficient. This has made the use of simple heat engines to harvest even moderate amounts of energy impractical. In addition areas where there are larger temperature differences to exploit, such as around sub ocean volcanic features, are impractical to set up traditional heat engines due to constraints of access.

Heat engines can come in both solid state forms such as shown in FIG. 1 which is a typical implementation of a mechanical closed cycle Stirling engine. Here heat is applied to the displacer piston 105. As the gas of the system (typically air) heats up it pushes the piston in to the region with the cooling fins 110. The action of the piston turns the wheel 115 which also pushes a second compressor piston 120. This piston pushes air back in to the displacer piston which in turn, after enough cooling returns to the heated area of the piston to repeat the cycle. The rotational energy of the such an engine can be used to turn the armature of an electrical generator creating electricity. As noted the maximum efficiency for small temperature differences will be low (much lower than the Carnot limit). Another approach to creating electricity from heat differences is to use solid-state means such as depicted in FIG. 2. Here 200 represents the hot side of a Peltier device and 205 represents a the cold side. Individually there may be hundreds of small junctions comprising the device. The output is a voltage developed across the electrical leads 210. Many types of solid state thermopiles exist for converting heat directly to electricity without mechanical steps.

### OBJECTS AND ADVANTAGES

The present invention allows the use of multiple small thermal differences to create a larger stabilized electric voltage which is both fixed in polarity and magnitude across an entire day. The present invention also presents simple cost effective ways to harvest ambient energy which is not typically accessible such as that in the deep ocean with traditional mechanical machinery and minimizes impact to the environment.

### LIST OF FIGURES

FIG. 1 a typical mechanical Stirling type heat engine.

FIG. 2 depicts a solid state thermopile such as a Peltier junction.

FIG. 3 shows a simple embodiment of the present invention

FIG. 4 shows an enhancement of the present invention using circulating fluids

FIG. 5 shows an embodiment of the present invention used outdoors

FIG. 6 shows an embodiment of the present invention used in conjunction with a large body of water.

FIG. 7 depicts an array of implementation of the present invention.

FIG. 8 depicts an embodiment of the present invention used in a large body of water such as an ocean or deep lake.

FIG. 9 depicts an embodiment of the present invention used in a large body of water which contains a thermal feature such as volcanic activity

FIG. 10 depicts a diagrams for thermal switches as are used in FIG. 7 and in later figures.

FIG. 11 depicts a close up view of the present invention with a thermal switch.

FIG. 12 depicts a type of thermal switch based on gas pistons

FIG. 13 depicts alternative types of gas piston based switches

FIG. 14 depicts a thermal switch which is completely solid-state (electronic) in nature

FIG. 15 depicts a block diagram of a 2:1 combiner for use in array type applications of the present invention

FIG. 16 depicts the combiner in action

FIG. 17 depicts the combiner in action

FIG. 18 depicts the combiner in action

FIG. 19 depicts the combiner in action

FIG. 20 depicts issues of paralleling voltage sources

FIG. 21 depicts a 3-way version of the combiner

FIG. 22 depicts the use of combiners to achieve regulation

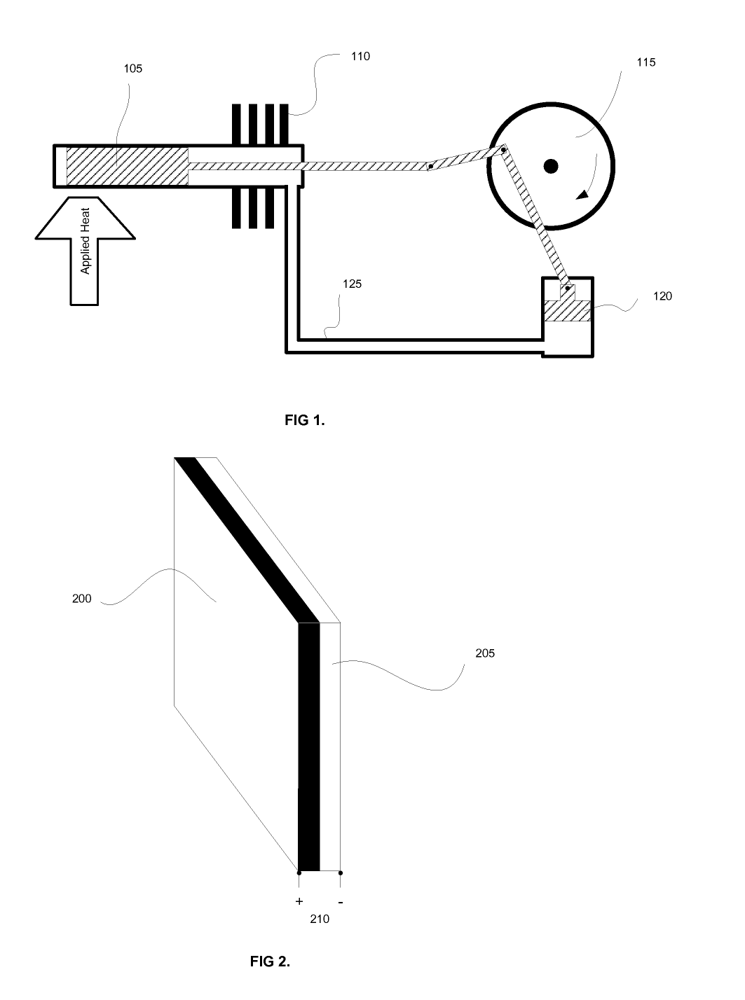

### DESCRIPTION OF THE INVENTION

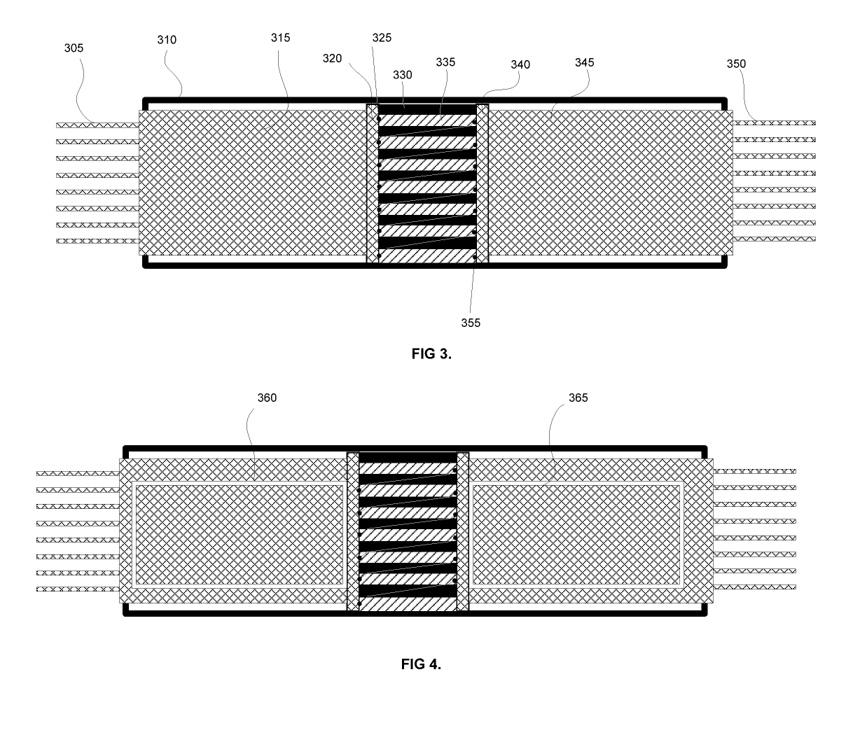

The basic unit of the present invention is presented in FIG. 3. Here two thermal temperature differences are presented at each side of the device. Heat sink 305 is attached to heat spreader plate 325 via a heat conducting path 315. The same is true on the opposite side heat sink 350 is attached to heat spreader plate 340 via heat conducting pat 345. A series of thermopile junctions in series 335 and separated by thermal insulators 330, which force heat flow through the junctions are in the center. Electrodes 325 and 355 provide electrical output whose polarity is dependant on which side of the apparatus is hotter.

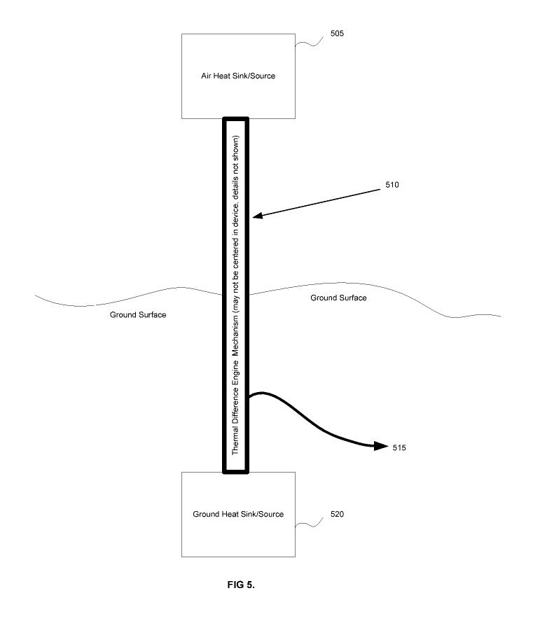

FIG. 4 depicts extra heat pipes 360, 365 in the heat conduction paths which can be filled with a fluid and may or may not be actively pumped or can be passively pumped via valves. This can help increase the efficiency of the heat transfer to the thermopile core.

FIG. 5 depicts the present invention in use with one end in the ground 520 and the other in the air 505. Depending on the temperature the either the ground or the surrounding air will be hotter. This forms a voltage on the thermopile 510 which can be tapped for energy 515. This can be maximized by choosing places where the day to night temperature is most extreme such as the desert. During the day the air will increase in temperature and at night sharply decrease. Since the ground lags in temperature the difference can be tapped for energy. Note the this will result in a sinusoidal type voltage with a period of approximately one day.

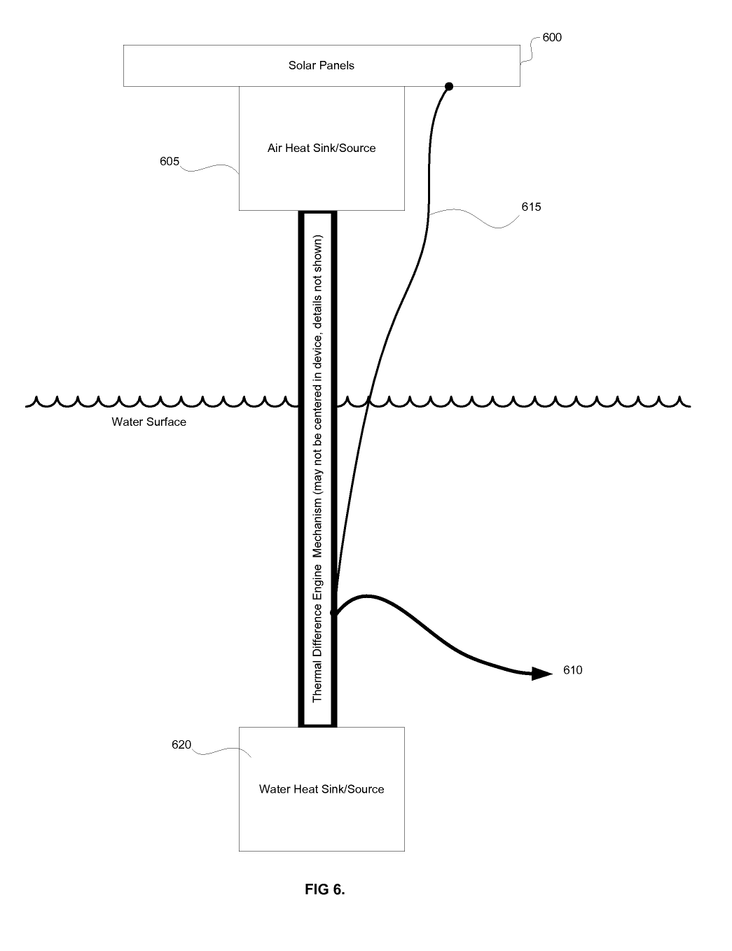

FIG. 6 depicts a similar setup over a large body of water. Here the air heat sink is 605, the water heat sink is 620, power is provide through interface 610. In addition solar panels have been added 600 which can provide additional energy harvesting during the daylight hours. A cable 615 allows the combining of the two power sources in to a single power output.

FIG. 7 depicts the entire setup as an array allowing greater voltage and current to be developed.

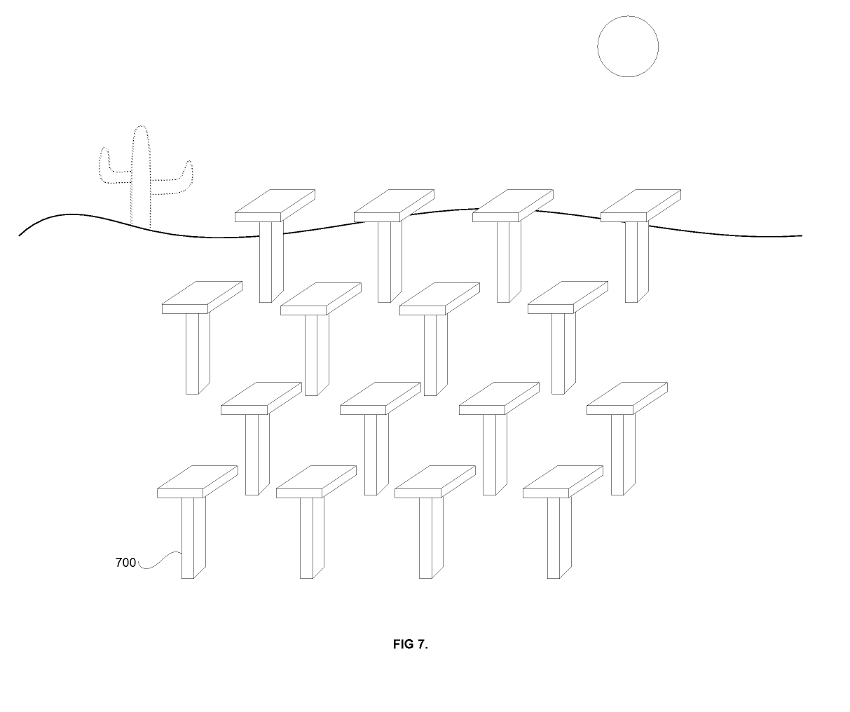

FIG. 8 depicts the present invention harvesting thermal energy from the ocean or other large body of water. Water is taken in from the intake 820 and transported via path 805 to the thermal difference engine (TDE) apparatus 800. There it is interface with another heat sink 825 which takes warmer water from the surface and then returns the water via path 810 to an outtake valve 815. Electrical power is delivered through interface 830. Note that since the output water can be delivered back the body of water at the thermocline which matches its temperature thereby reducing impact to the environment. Water can be actively pumped or if a suitable current can be found then it can be passively transported through the piping system.

FIG. 9 depicts the present invention exploiting a volcanic feature on the ocean floor. Here feature 940 heats water at the intake 920 where it goes through transport pipe 905 and is delivered to the TDE apparatus 900. The TDE is dissipating the heat through heat sink 925 and expels it through path 910 to exhaust vent 915. Note that like in FIG. 8 the exhaust outlet can be matched to a thermocline to minimize the effect of temperature on marine environments. Passive or active pumping may be used.

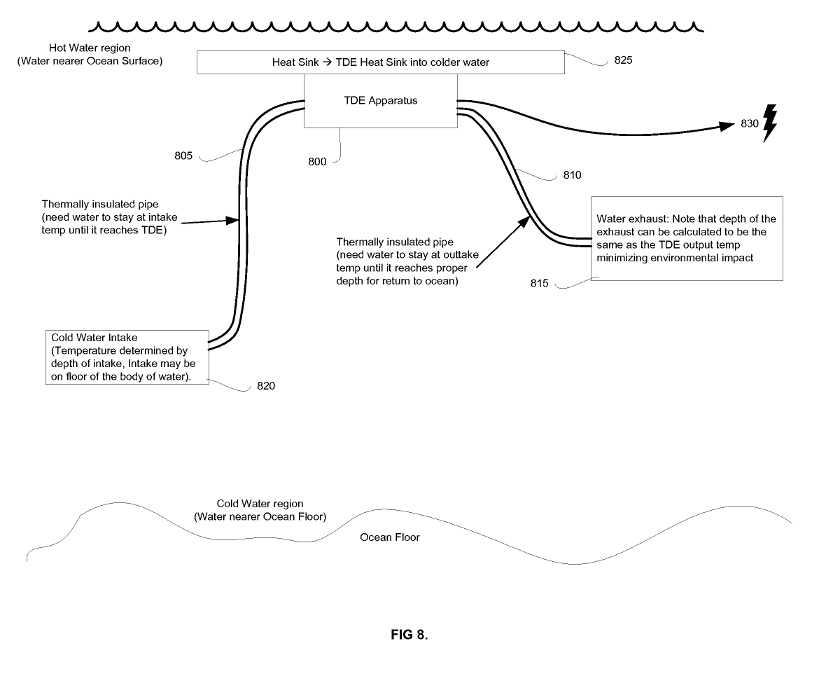

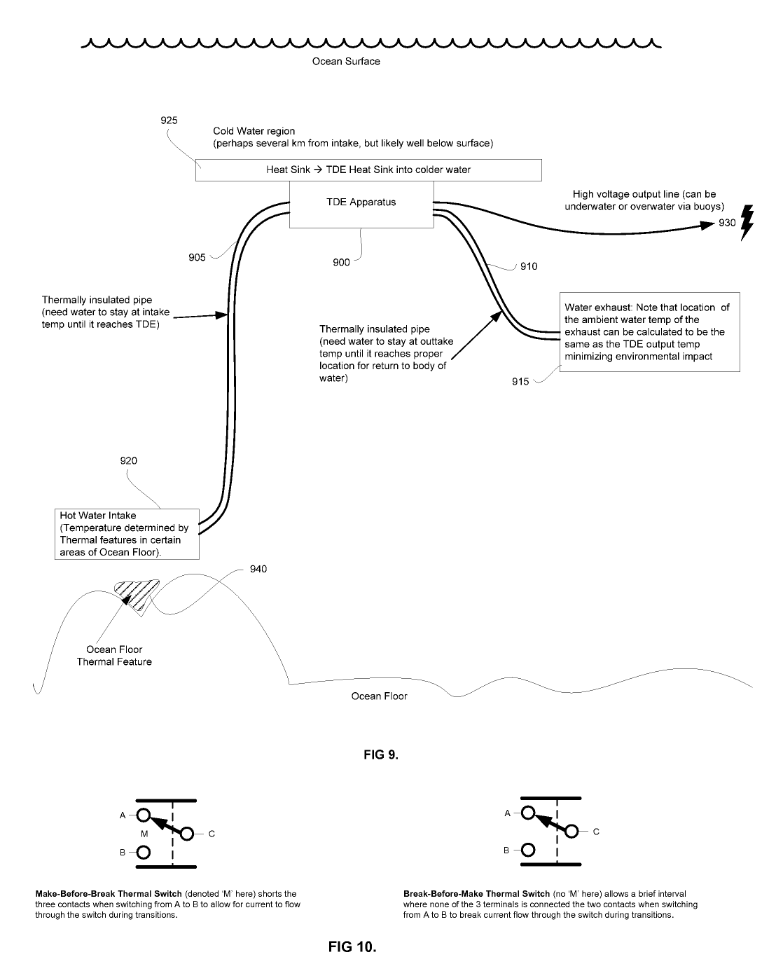

The previous figures detail the invention and its use in many environments. However the need for fixed polarity of voltage and constant magnitude of the voltage also needs to be a achieved. This is also a portion of the invention and is detailed here in FIGS. 10 to 21.

FIG. 10 shows a nomenclature for some thermal switches—either make before break (useful in parallel combiners discussed shortly) or break before make (discussed in series combiners discussed shortly).

FIG. 11 depicts a thermal switch assembly, intended to be co-located with the thermal difference engine. Here the switches 1135 and 1130 switch the output polarity of the thermopile 1125 output electrodes by detecting the heat between plates 1110 and 115. Each switch contains two plates (such as 1115 and 1120) which allows the switch to sense the temperature. No matter which plate is hotter the thermal switches allows the output voltage polarity of the thermopile to remain fixed. Hence rectification of the electrical output is accomplished using thermal switches.

FIG. 12 depicts a gas-piston setup for implementing such a switch as symbolized by FIG. 10 and used in FIG. 11. Two heat sink interfaces are at each end of the assembly as described by 1210 and 1205. Two gas filled areas (typically a pressurized inert gas) occupy chambers 1235 and 1230. Three electrodes 1252, 1242, and 1222 form the contacts of an SPDT switch. A conductive plunger 1225 is pushed to make contact between the middle electrode and either one of the other two electrodes depending on the relative (not absolute) temperature difference. As depicted the switch is a break before make switch.

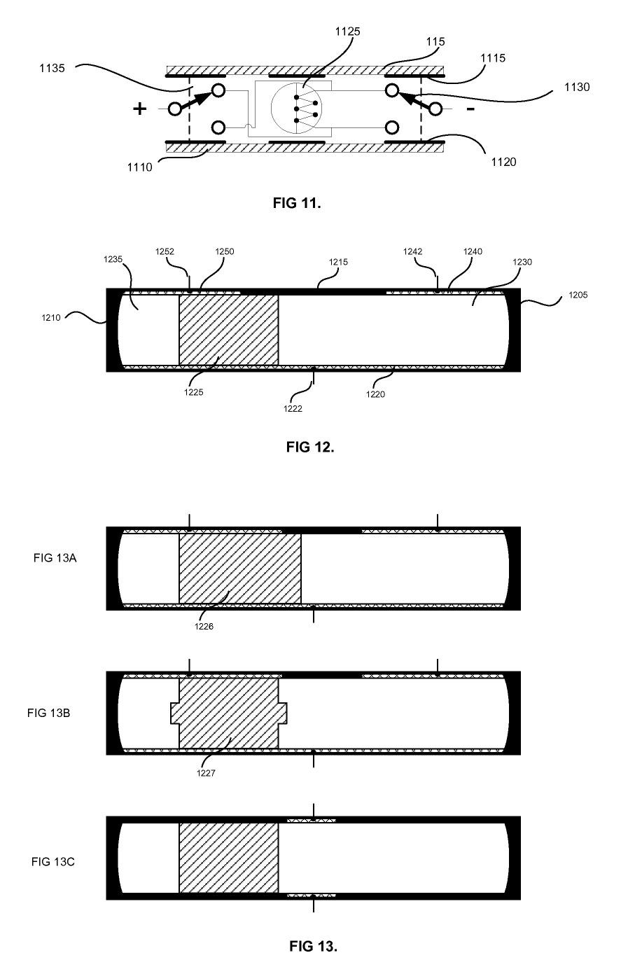

FIG. 13 depicts variants of the switches. In FIG. 13A the plunger 1226 is larger to create a make before break switch. In FIG. 13B the plunger has been given bumpers to help provide mechanical relief if extreme temperature differences are encountered. In FIG. 13C. The electrodes are re-arranged to provide an connection only when the temperate difference is zero (e.g. a zero temp detect switch). Without loss of generality it can be seen that many variants such as DPDT etc can be create with gas piston switches.

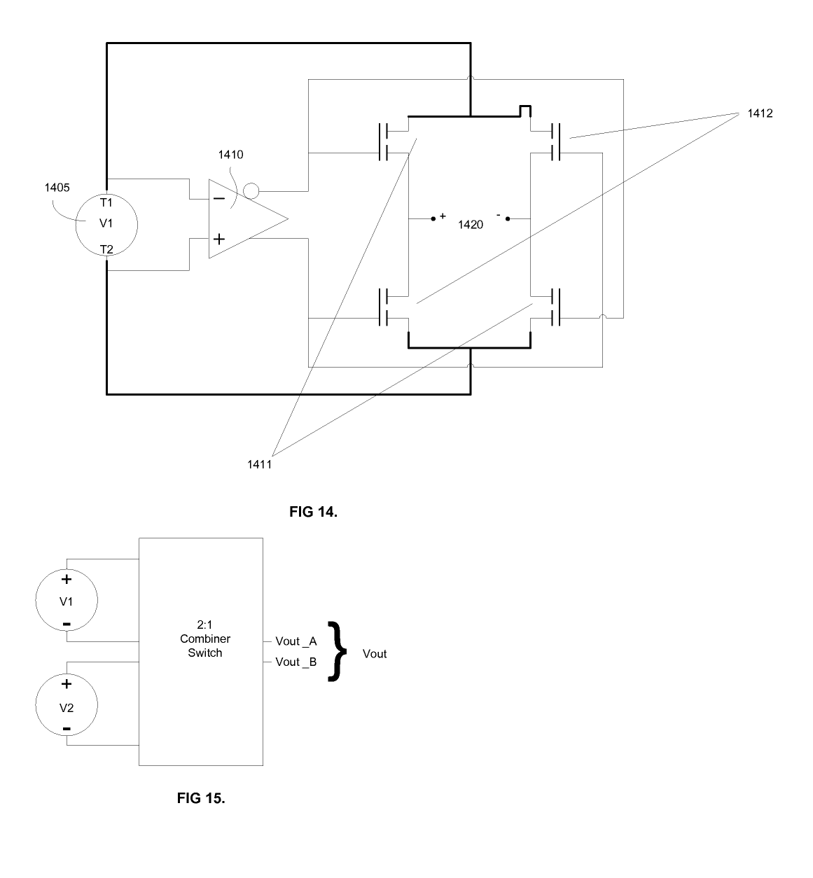

FIG. 14 depicts a solid-state implementation of the switch diagram in FIG. 11. Here the thermopile outputs a voltage from 1405 and a detector 1410 drives a active bridge rectifier signified by the semiconductor switches shown in pairs 1412 and 1411 to maintain a fixed polarity output. A diode system can also be used but diodes may have large voltage drops which would unnecessarily lower efficiency. Note the use of active electronics requires power drive circuits not shown.

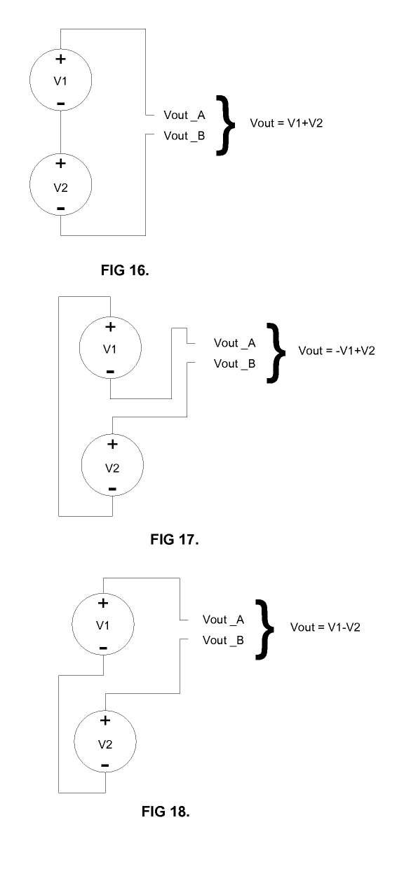

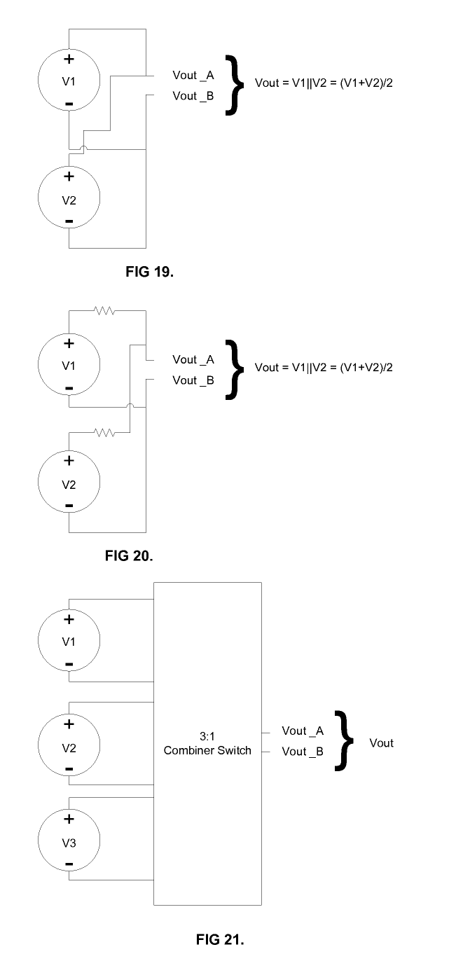

FIG. 15 depicts a combiner where two thermal difference engines of fixed polarity (using the methods of FIGS. 10 to 14) are combined to produce a new voltage. The combiner may include both the rectification and regulation methods can be accomplished via careful thermal switch layout design. Examples of the types of outputs of the combiner are shown in FIG. 16 (summation), FIG. 17 (minus V1 plus V2), FIG. 18 (plus V1 minus V2). FIG. 19 depicts a simple attempt at paralleling the voltages of the thermal difference engines. Note that this can cause a “fight” of the two voltage sources, hence if paralleling is desired careful balancing should be used as in FIG. 20. FIG. 21 generalizes this concept to include 3 thermal difference engines. Now several switch configurations can be used to create a the desired output voltage and polarity, As the number of thermal difference engines is increased the precision of the control is also increased.

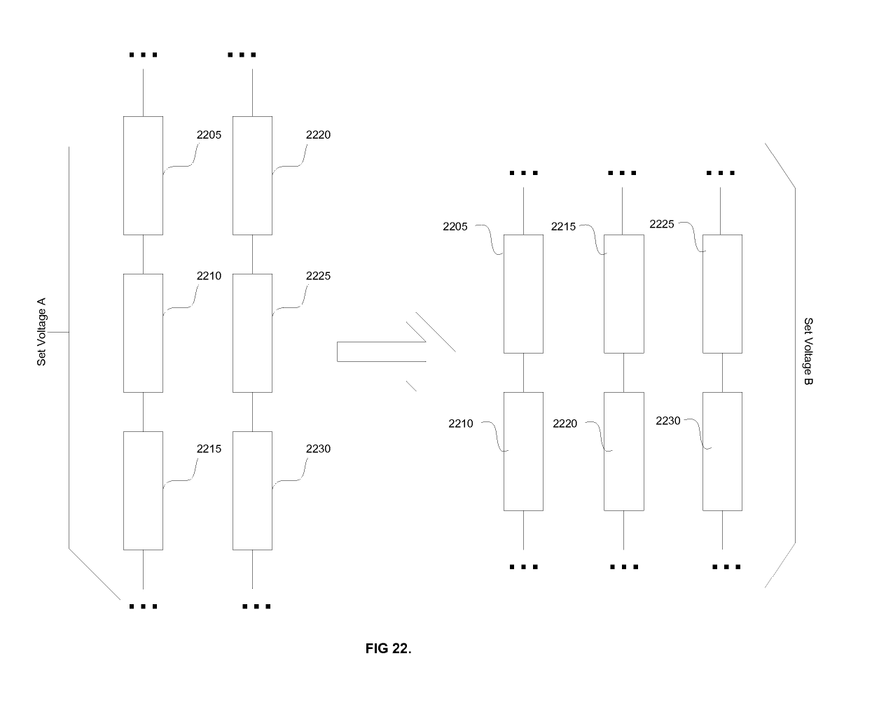

FIG. 22 depicts the output of multiple combiners where a Set Voltage A from one configuration of thermal difference engines can be made in to another voltage B by recombining individual thermal difference engines. Here we see two sets in series 2205, 2210. and 2215 paralleled with 2220, 2225, and 2230. If the temperature changes then to maintain the same output (for example if the temp rises) then the individual voltages produced by the thermopiles will increase. The same voltage can be delivered by reconfiguring the thermopiles in to a new orientation shown on the right. Here 2205 and 2210 are in series. This is repeated for 2215 plus 2220, and 2225 and 2230. This allows voltage B to be the same as voltage A even when the temperature changes.

What is claimed is:

1. A system for harvesting heat energy in to electrical energy comprising two heat-sinks, a thermopile junction set, and an insulating jacket.

2. A system of claim 1 where a working fluid assists in the spreading of the heat.

3. A system of claim 1 where one heat sink is in the ground and the other is placed in the air.

4. A system of claim 1 where one heat sink is in the ground and the other is in water.

5. A system of claim 1 where one heat sink is in the water and the other is in the air.

6. A system for regulation of thermal difference engine output voltage and polarity consisting of thermally activated switches.

7. A system of claim 6 where the regulation function is achieved by paralleling and series-connecting the various individual thermal difference engines.

8. A system of claim 6 based on Gas-Thermal switches.

9. A system of claim 6 based on electronic circuits.

10. A system of claim 6 based on bi-metal (thermostatic) switches.

11. A system of claim 1 where the ocean is used as the heat source and sink.

12. A system of claim 11 where an underwater/under ground heat source is used as the hot side temperature source.

13. A system of claim 11 where natural currents are used to transport the working fluid (water).

14. A system of claim 11 where the output waste water is deposited at the thermocline where it naturally occurs to minimize impact on the marine environment.

15. A system of claim 11 which uses a mechanical heat engine to create electricity.
